(19) United States
(12) Patent Application Publication
(10) Pub. No.: US 2002/0036352 A1
(43) Pub. Date: Mar. 28, 2002

(54) Method for fabricating semiconductor device capable of reducing parasitic capacitance and semiconductor device thereby

(76) Inventors: Jae-Hak Kim, Seoul (KR); Hong-Jae Sin, Seoul (KR); Jae-Hyun Han, Seoul (KR)

Correspondence Address: MARGER JOHNSON & McCOLLOM, P.C., 1030 S.W. Morrison Street, Portland, OR, 97205, US

(21) Appl. No.: 09/919,340

(22) Filed: Jul. 30, 2001

(30) Foreign Application Priority Data
Jul. 29, 2000 (KR) 2000-43961

(51) Int. Cl. H01L 21/4763; H01L 23/58; H01L 21/302

(52) U.S. Cl. 257/774; 257/760; 438/629; 257/642; 438/725

(57) ABSTRACT

Disclosed is a semiconductor device capable of reducing parasitic capacitance and a method thereof, the method including the steps of depositing sequentially an inorganic silicon oxide layer and a low dielectric constant organic silicon oxide layer on a substrate, forming a partial trench with a predetermined depth in the organic silicon oxide layer by patterning, oxygenating an inner wall of the partial trench, and forming a trench by etching the partial trench with hydrofluoric acid (HF).

This application relies for priority upon Korean Patent Application No. 2000-43961, filed on Jul. 29, 2000, the contents of which are herein incorporated by reference in their entirety.

### FIELD OF THE INVENTION

The present invention relates to semiconductor devices capable of reducing parasitic capacitance between interconnections, and more particularly to a method for fabricating semiconductor devices having a low dielectric constant layer as an interlayer insulating layer where a conductive interconnection is formed therein.

### BACKGROUND OF THE INVENTION

As interconnection density and integrated circuit density increase in semiconductor devices, the spacing between adjacent conductors decreases. As the spacing between adjacent conductors decreases, there is a corresponding increase in coupling capacitance (or mutual capacitance) between conductors. Adjacent conductors that exhibit a coupling or mutual capacitance form what is called a parasitic capacitor. In a typical integrated circuit device, parasitic capacitors are physically distributed over an integrated circuit and affect electrical operations therein. As the spacing between adjacent conductors decreases, the capacitance value of parasitic capacitors in an integrated circuit increase. Further, the topological widths of interconnections are decreased as circuit density is increased, causing an increase in the resistance of the interconnection.

The increased resistance between the interconnections and the increase in parasitic capacitance resulting from decreased spacing between adjacent conductors increase the total resistance in a circuit. The increased resistance delays the electrical signal transmissions and causes a phase variation in the device. The delay of the signal transmission is called a resistance-capacitance (RC) delay, which reduces the efficiencies and capacities of the semiconductor device. It is therefore important to provide a technique to reduce the parasitic capacitance and the resistance between interconnections.

One method for reducing the resistance between the interconnections is utilizing a material having a low specific resistance like copper (Cu) as a material for the interconnections. However, it is not profitable to use Cu for forming the interconnections, for copper has an unacceptably low etch rate in known acid etching methods. Instead, a damascene process may be used to overcome the patterning difficulty. The damascene process may be used for fabricating the interconnections using a self-aligned method, or for other reasons.

Meanwhile, in order to reduce the parasitic capacitance, there is a method of reducing the widths of the interconnections with increasing intervals thereof. However, because of problems such as a design rule and the resistance involved in the interconnection widths, it would be preferable to lower a dielectric constant of an insulating material filling the intervals of the interconnections. Briefly, it is necessary to use a low dielectric constant material as an interlayer insulating material. The low dielectric constant materials are mostly silsesquioxane series materials such as methyl silsesquioxane (MSSQ) and phenyl silsesquioxane (PSSQ). The dielectric constant of MSSQ is 2.7, which is lower than the dielectric constant of the conventional silicon oxide of 4.

However, the silsesquioxane includes an alkyl or aryl group. It is therefore etched relatively slowly when using a CFₓ etchant and therefore the processing time is longer. Further, there is a problem in a dual damascene process where contact holes for connecting layers (upper and lower layers) and interconnection lines are formed in a predetermined portion of a trench, after the trench is formed to fill an interconnection material. That is, it is hard to control a depth of the trench when the trench is formed in the interlayer insulating layer with a uniform depth.

A well-known method for controlling the depth of the trench is forming an etch stop layer in the middle of the interlayer insulating layer. However, as the etch stop layer generally uses silicon nitride having a higher dielectric constant of 8, it offsets the benefit of using the low dielectric constant material as the interlayer insulating layer, and requires an additional processing step to form the silicon nitride layer.

### SUMMARY OF THE INVENTION

It is therefore an object of the present invention to provide a method capable of forming a trench with an uniform depth without using an etch stop layer in an interlayer insulating layer made of a low dielectric constant material.

It is another object of the invention to provide a method for fabricating a semiconductor device capable of reducing parasitic capacitance between interconnections.

It is still another object of the invention to provide a method for fabricating a semiconductor device capable of suppressing a resistance-capacitance (RC) delay.

It is still further another object of the invention to provide a method, especially profitable for a damascene process, capable of improving a processing margin of a trench formation for interconnections.

In order to attain the above objects, according to an aspect of the present invention, there is provided a method for fabricating a semiconductor device, the method including the steps of depositing sequentially an inorganic silicon oxide layer and a low dielectric constant organic silicon oxide layer on a substrate, forming a partial trench with a predetermined depth in the organic silicon oxide layer by patterning, oxygenating the partial trench, and forming a trench by etching the partial trench with hydrofluoric acid (HF).

The present invention is appropriate for the damascene process, in particular, for a dual damascene process using the low dielectric constant silicon oxide layer as an upper layer, and generally includes an accompanying step of forming a contact hole by etching a predetermined portion of the trench.

According to another aspect of the invention, a semiconductor device includes an interlayer insulating layer formed of an upper interlayer insulating layer and a lower interlayer insulating layer. The upper interlayer insulating layer, made of an organic silicon oxide of a low dielectric constant for a conductive interconnection, includes an interconnection having a thickness of the same or more as that of the upper layer. The lower interlayer insulating layer, made of an inorganic silicon oxide, includes a contact plug for connecting the interconnection to a lower conductive region. In particular, the upper and lower interlayer insulating layers are directly adjacent one another without an intervening etch stop layer of silicon nitride.

### BRIEF DESCRIPTION OF THE DRAWINGS

A more complete appreciation of the present invention, and many of the attendant advantages thereof, will become readily apparent as the same becomes better understood by reference to the following detailed description when considered in conjunction with the accompanying drawings in which like reference symbols indicate the same or similar components, wherein:

FIG. 1 is a schematic cross section along the line direction of an interconnection, showing the semiconductor device forming an interconnection and a contact plug in an interlayer insulating layer using a dual damascene process according to a preferred embodiment of the present invention;

FIGS. 2 through 6 are cross sections along the width direction of an interconnection, showing the sequence of process steps using the dual damascene process according to a preferred embodiment of the present invention; and

FIGS. 7 through 9 are schematic sections showing the sequence of process steps to show an ashing damage layer in a uniform thickness when an organic silicon oxide layer is subject to an ashing treatment according to a preferred embodiment of the present invention.

### DESCRIPTION OF THE PREFERRED EMBODIMENT

It should be understood that the description of this preferred embodiment is merely illustrative and that it should not be taken in a limiting sense. In the following detailed description, several specific details are set forth in order to provide a thorough understanding of the present invention. It will be obvious, however, to one skilled in the art that the present invention may be practiced without these specific details.

As explained in the aforementioned description in the background, it is preferable to use a low dielectric constant organic silicon oxide layer as an interlayer insulating layer. However, if the interlayer insulating layer is formed entirely of the low dielectric constant organic oxide layer, it is difficult to uniformly control the depth of a trench and to interlay an etch stop layer in the layer. In the present invention, two layers having different etching characteristics are formed and thereby the trench is precisely formed to have a uniform depth by an etching process using the different etching characteristics of the two layers.

In some instances, the upper interlayer insulating layer is etched faster than a lower interlayer insulating layer when using a specific etchant. In that case, if the trench in the upper interlayer insulating layer is etched to the same depth as the thickness of the upper interlayer insulating layer, the trench may be formed with the almost uniform depth without using an etch stop layer. In other words, if a part is etched faster, the part is consequently faced with the lower interlayer insulating layer having a lower etch rate than that of the upper layer. Until the upper interlayer insulating layer is entirely etched, the lower interlayer insulating layer is not etched much, so that a deviation on the trench depth over all regions is decreased.

When the interlayer insulating layer is divided into two layers, the upper interlayer insulating layer is made of the low dielectric constant material. However, the organic silicon oxide layer made of methyl silsesquioxane (MSSQ) of the conventional low dielectric constant material is not easily etched by a silicon oxide etchant due to a carbonic element thereof. On the other hand, the lower interlayer insulating layer of an inorganic silicon oxide without containing the carbon ingredient is easily etched by the silicon oxide etchant.

If the etching process is not correctly controlled, the etching is rapidly advanced to the lower interlayer insulating layer of the inorganic silicon oxide, so that the desired depth of the trench may be exceeded, or an insulating facility may be degraded. Thus, it would be better to use the low dielectric constant silicon oxide for the upper and lower interlayer insulating layers equally in forming the trench in the uniform depth.

In the present invention, the upper interlayer insulating layer is formed as the low dielectric constant organic silicon oxide layer, while the lower interlayer insulating layer is formed as the inorganic silicon oxide layer by using a specific step where the organic silicon oxide layer can be etched faster than the inorganic silicon oxide layer.

Next, with reference to the accompanying drawings, an embodiment of the present invention will be explained in detail.

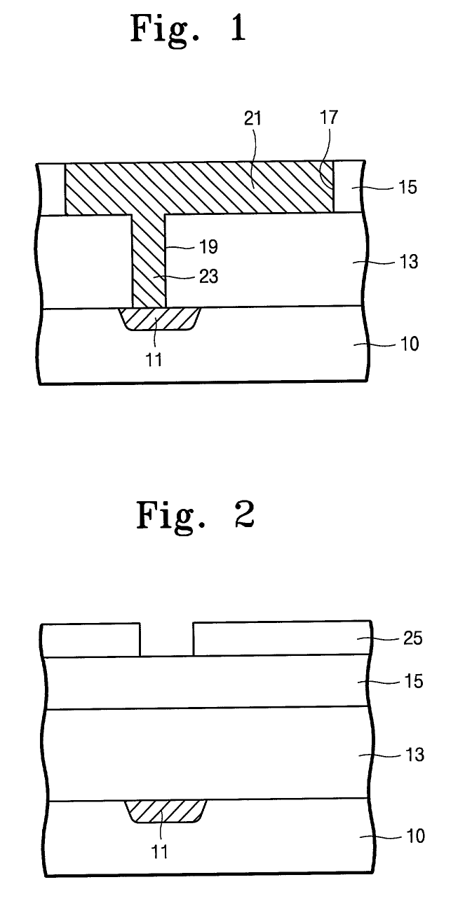

FIG. 1 is a schematic cross section along the line direction of the interconnection, showing the semiconductor device forming an interconnection and a contact plug in the interlayer insulating layer using the dual damascene process according to a preferred embodiment of the present invention.

Referring to FIG. 1, a lower inorganic interlayer insulating layer 13, made using an inorganic silicon oxide precursor such as hydrogen silsesquioxane (HSSQ), is coated on a substrate 10 having a conductive region 11 using conventional spin-on-glass (SOG) methods Methyl silsesquioxane (MSSQ) is then used in a CVD process to form thereon an upper interlayer insulating layer 15. A trench 17 is formed in the upper interlayer insulating layer 15, and filled with copper (Cu) to form an interconnection 21. A contact plug 23, also made of Cu, fills a contact hole 19 penetrating the layer 13 in a partial region under the trench 17. The contact plug 23 connects the Cu interconnection 21 filling the trench 17 to the conductive region 11 under layer 13.

The lower interlayer insulating layer 13 is made of silicon oxide using CVD or SOG and precursors such as conventional tetraethyleorthosilicate (TEOS), HSSQ, and SiOF containing insignificant amounts of carbon. The upper interlayer insulating layer 15 is necessarily formed to have a low dielectric constant with the organic silicon oxide expressed generally as silicon oxycarbonate (SiOC) such as MSSQ and phenyl silsesquioxane (PSSQ). The CVD is preferably utilized in forming the upper silicon oxide layer, rather than the SOG.

A metal filling the trench 17 and the contact hole 19 may be formed concurrently by the dual damascene process, and CVD tungsten or other low-resistance metals may be used instead of Cu.

FIGS. 2 through 6 are cross sections along the width direction of the interconnection, showing the sequence of process steps using the dual damascene process according to a preferred embodiment of the present invention.

Referring to FIG. 2, the inorganic silicon layer 13 is deposited on the substrate 10, which includes a conductive region 11 using CVD and using TEOS as the precursor. MSSQ is used to form the organic silicon oxide layer 15 with a thickness of 3000 through 4000 Å by CVD. Next, a photo resist pattern 25 is formed to define a trench etch mask for the damascene process.

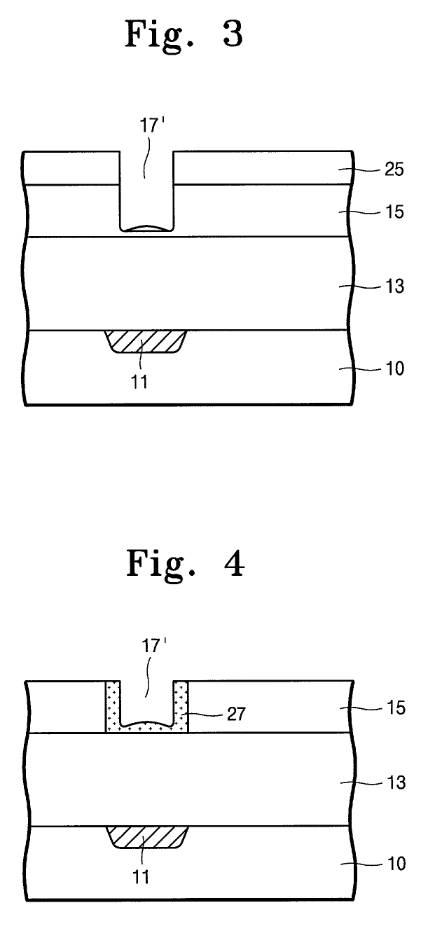

Referring to FIG. 3, a partial trench 17′ having a depth of 2000 through 3000 Å is etched in the organic silicon oxide layer 15 using photo resist pattern 25. The bottom of the partial trench 17′ is convex as shown in a general etching step where a center region is less etched.

Referring to FIG. 4, the substrate 10 having the partial trench 17′ is oxygenated by exposing an inner wall of the partial trench 17′ to an oxygen plasma, which is used in the ashing process to remove the photo resist pattern 25. The oxygenation may be performed after the photo resist pattern 25 is removed, but it is most effectively performed synchronously with the removal of the photo resist pattern 25 in the ashing process. Then, an ashing damage layer 27 is formed in a thickness of about 1000 Å in the inner wall of the partial trench 17′. Here, the thickness of the ashing damage layer 27 is dependent on ashing temperature, plasma formation power, plasma density, pressure, and so on.

During the ashing process, carbonic ingredients of the organic silicon oxide layer 15 as the upper interlayer insulating layer are diffused out in a region of the ashing damage layer 27, and oxygen of the oxygen plasma is diffused into the layer, which creates a carbon oxide. The carbon oxide is discharged to the outside of a process chamber in gaseous phase. As a result, the layer 15 becomes the inorganic silicon oxide having no carbon-containing ingredients. As the lower inorganic silicon oxide layer 13 does not contain carbon-containing ingredients, the ashing damage layer 27 is not extended to the lower inorganic silicon oxide layer 13, but is limited to the upper organic silicon oxide layer 15.

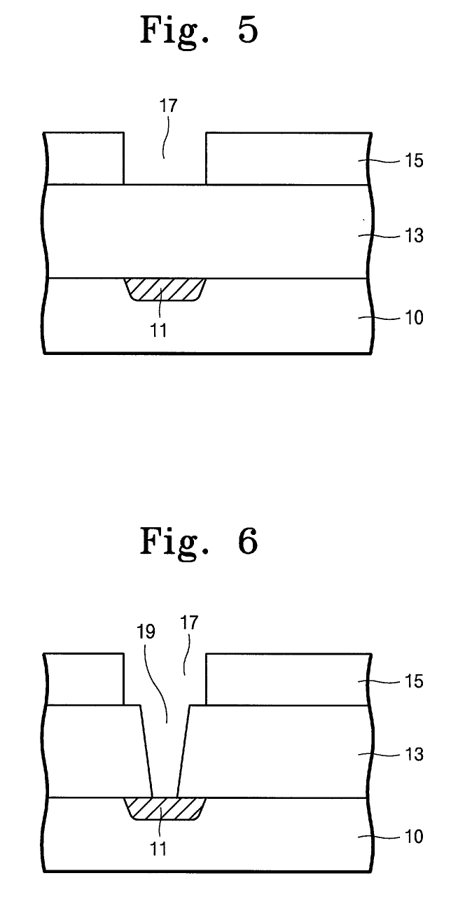

Referring to FIG. 5, a wet etching step is then performed using an etchant of hydrofluoric acid (HF) on the substrate 10, including the etching damage layer 27 shown in FIG. 4. In alternative embodiments, a cleaning step may be performed without an additional etching process if the cleaning solution contains primarily HF. Here, the ashing damage layer 27 is removed rapidly, so that the trench 17 is completely formed to have a greater width and depth than the partial trench 17′. The trench 17 is preferably formed to have a depth that is the same as the thickness of the organic silicon oxide layer 15.

Though there are differences depending on the HF concentration in the etchant or cleaning solution, it takes about 3 to 5 seconds in the etching process where a conventional buffered oxide etchant (BOE) is applied. The rapid etching is caused by weak atomic bondage of the etching damage layer 27 in which the carbonic ingredients (i.e. methyl-group) have been eliminated.

The inorganic silicon oxide layer 13 is seldom etched for such a short time, even though the layer 13 is exposed by removing the ashing damage layer 27. Thus, the depth of the trench 17 does not exceed the thickness of the organic silicon oxide layer 15. Consequently, the trench 17 for the interconnection is formed with a uniform depth and width. Further, the width of the trench 17 is defined for the organic silicon oxide layer 15, exposed on a sidewall by removing the ashing damage layer 27, has a low etch rate by HF etchant.

Referring to FIG. 6, the contact hole 19 is formed by patterning the lower inorganic silicon oxide layer 13, which is exposed after forming the trench 17. It is preferable to use an anisotropic dry etch for the patterning step. A photo resist pattern (not shown) to form the contact hole 19 may be removed only at a region of the contact hole 19, or removed along with a line including the region of the contact hole 19. In that case, though the organic silicon oxide layer 15 is exposed in other regions except the region of the contact hole 19, only the inorganic silicon oxide layer 13 in the region of the contact hole 19 is removed without damage on the surface because the etching speed of the organic silicon oxide layer 15 is slower than that of the inorganic silicon oxide layer 13.

Thereafter, the metal such as Cu or tungsten is deposited in the contact hole 19 and the trench 17 by the CVD or other conventional methods. A metal layer stacked on the upper interlayer insulating layer 15 is removed by planarization, e.g., chemical-mechnical polishing (CMP), and the interconnection is completely formed therein.

The aforementioned descriptions take the dual damascene process as an example, but all the applications using the damascene process with the high interconnection density are possible.

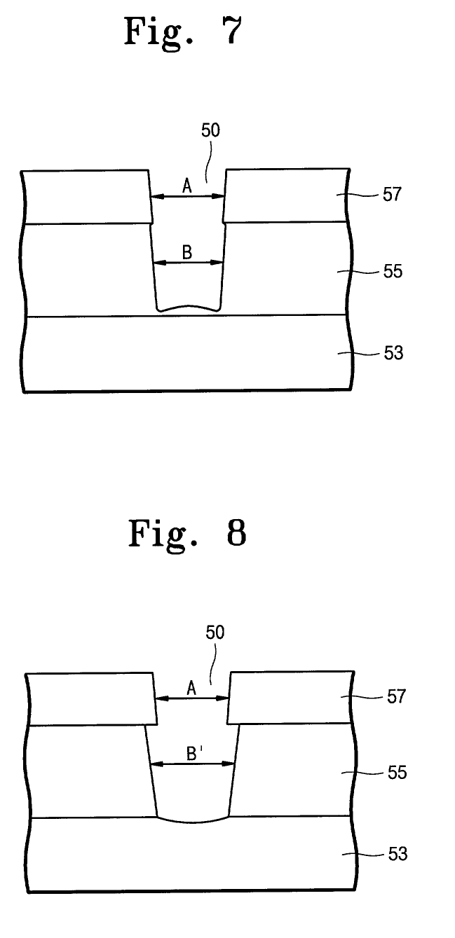

FIGS. 7 through 9 are schematic sections showing the sequence of process steps in which the ashing damage layer is formed in a uniform thickness when an organic silicon oxide is subjected to the ashing treatment according to a preferred embodiment of the present invention.

Referring to FIG. 7, an inorganic silicon layer 53 is formed using a TEOS precursor, a methyl silsesquioxane-group layer 55 is deposited using HOSP, which is available commercially from Honeywell International, Inc., and a second inorganic silicon layer 57, also using TEOS as a precursor, are sequentially deposited on a substrate (not shown). Next, a contact hole 50 having a width of A and B in the upper layer 57 and layer 55 are formed. There is a discontinuity on side slopes at a boundary between layer 57 and layer 55. The bottom of the contact hole 50 almost reaches to the lower layer 53. A photo resist pattern (not shown) is removed by ashing, which also oxygenates the inner wall of the contact hole 50.

FIG. 8 shows a step of treating the oxygenated contact hole 50 with HF solution for 3 seconds. The width is extended from B to B′ in layer 55. As the contact hole 50 almost reaches the lower end of the lower layer 53, forming a concave shape that is a typical profile after a wet etching, the depth is not extended more.

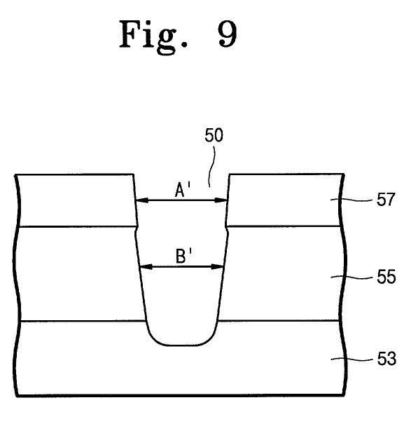

FIG. 9 shows a step of treating the oxygenated contact hole 50 with HF solution for 10 seconds. There is not significant extension of the width in the layer 55. However, depending on the time of the etch, the contact hole 50 is extended in a width from A to A′ in the upper layer 57 and is further deepened in the lower TEOS layer 53.

As described above, the ashing damage layer of the methyl silsesquioxane layer is formed with a uniform thickness by the ashing process, and the etching speed thereof in HF etching is too high.

According to the semiconductor device of the present invention, the trench is formed with a uniform depth as the thickness of the organic silicon oxide layer, and in particular, with the uniform depth in the low dielectric constant organic silicon oxide layer without using the etch stop layer.

Consequently, the semiconductor device of the present invention is able to improve the efficiencies of the device by suppressing a resistance-capacitance (RC) delay in the interconnections.

Although the preferred embodiments of the present invention have been disclosed for illustrative purposes, those skilled in the art will appreciate that various modifications, additions and substitutions are possible, without departing from the scope and spirit of the invention as described in the accompanying claims.

What is claimed is:

1. A method for fabricating a semiconductor device comprising the steps of:
sequentially depositing an inorganic silicon oxide layer on a substrate and an organic silicon oxide layer of a low dielectric constant on the inorganic silicon oxide layer;
forming a partial trench with a predetermined depth in the organic silicon oxide layer by patterning;
oxygenating an inner wall of the partial trench; and
forming a trench by etching the partial trench with hydrofluoric acid (HF).

2. The method of claim 1, the method further comprising the steps of:
depositing a conductive layer to fill the trench; and
removing a portion of the conductive layer stacked on a top surface of the organic silicon oxide layer by chemical-mechanical polishing (CMP).

3. The method of claim 1, the method further comprising the steps of:
forming a photo resist pattern exposing a predetermined portion of a bottom of the trench after the step of forming the trench; and
forming a contact hole by etching the inorganic silicon oxide layer with the photo resist pattern.

4. The method of claim 1, wherein the oxygenation is performed in an ashing step for the photo resist pattern formed during the patterning step.

5. The method of claim 1, wherein the oxygenation is performed at a region having a thickness less than 1000 Å in an exposed region of the organic silicon oxide layer.

6. The method of claim 1, wherein the HF wet etching is performed in 5 seconds by a buffered oxide etchant (BOE).

7. A semiconductor device comprising:
a substrate having a conductive region formed thereon;
an inorganic silicon oxide layer formed on the substrate and convering at least a portion of a conductive region formed thereon;
an organic silicon oxide layer of a low dielectric constant formed on the inorganic silicon oxide layer;
a conductive interconnection formed with a predetermined line width in a depth of the same or more as a thickness of the organic silicon oxide layer; and
a contact plug penetrating the inorganic silicon oxide layer in a predetermined part for connecting electrically the conductive interconnection to the conductive region of the substrate.

8. The semiconductor device of claim 7, wherein the contact plug and the conductive interconnection are simultaneously formed in a manufacturing step.

9. The semiconductor device of claim 8, wherein the contact plug and the conductive interconnection are made of copper.

10. The semiconductor device of claim 7, wherein the organic silicon oxide layer is a silicon oxi-carbonate (SiOC) layer of silsesquioxane series containing carbon.

11. The semiconductor device of claim 10, wherein the organic silicon oxide layer is formed by chemical vapor deposition (CVD).
